(19) United States
(12) Patent Application Publication
(10) Pub. No.: US 2010/0328105 A1
(43) Pub. Date: Dec. 30, 2010

(54) METHOD AND APPARATUS FOR ENERGY SELF SUFFICIENT AUTOMOBILE DETECTION AND REIDENTIFICATION

(76) Inventors: Mehdi Kalantari Khandani, Bethesda, MD (US); Masoud Hamedi, Columbia, MD (US); Ali Haghani, Columbia, MD (US)

Correspondence Address: TR Patents, L.L.C., 10351 Southern MD BLVD Suite 102, P.O Box 361, Dunkirk, MD, 20754, US

(21) Appl. No.: 12/822,731

(22) Filed: Jun. 24, 2010

Related U.S. Application Data
(60) Provisional application No. 61/220,062, filed on Jun. 24, 2009.

(51) Int. Cl. G01R 15/00; G08G 1/01

(52) U.S. Cl. 340/933

(57) ABSTRACT

A device is provided for detecting an automobile. The device includes a body, an energy harvesting portion, a sensing portion, a processing portion and a communication portion. The energy harvesting portion can harvest energy from a source external to the body. The sensing portion can output a signal and has a low-energy detector and a high-energy detector. The low-energy detector can detect a first parameter using a first level of energy. The high-energy detector can detect a second parameter using a second level of energy, wherein the first level of energy is lower than the second level of energy, and wherein the signal is based on the second parameter. The processing portion can output a signature based on the signal. The communication portion can wirelessly transmit an output signal based on the signature. The energy harvesting portion can supply energy to each of the sensing portion, the processing portion and the communication portion.

The present application claims priority from U.S. Provisional Application No. 61/220,062 filed Jun. 24, 2009, the entire disclosure of which is incorporated herein by reference.

### BACKGROUND

Each year, motor vehicle accidents account for large number of fatalities and injuries. Traffic congestion and associated delays such as air pollution and added fuel consumption poses major concerns to the public.

Increasing the efficiency of the current transportation system by using real time traffic surveillance is one of the most important components of such approach. The real time travel information is an important requirement for advanced travel advisory systems.

Emergency management agencies such as police, fire department, and ambulance dispatchers may also benefit from the real time traffic information in routing their vehicles through the transportation network. Such applications require distributed data acquisition of traffic metrics such as speed, volume, and density. In such systems, automated traffic control is possible only through real time vehicular information over large number of points of the transportation system.

Conventional sensor technologies are bending plates, pneumatic road tubes, piezoelectric sensors, inductive loops, infrared, microwave-doppler/radar, passive acoustic, magnetic sensors, and video.

The existing data acquisition technologies in transportation systems suffer from the following drawbacks: (1) cost: majority of existing technologies require expensive instruments, which inhibits cost effectiveness of distributed measurements of the traffic in large number of points; (2) installation and maintenance: most of existing technologies need high maintenance, installation costs; and (3) energy efficiency: in most of exiting technologies the traffic measurement instruments consume a large amount of energy, and therefore, they need either large battery packs or connection to main power through wires.

FIG. 1 is a planar view illustrating a classic traffic measurement device known as inductive loop detector. In this figure a loop of wire 104 is installed on a road 100 and inside lane 110.

In order to detect an automobile 102 moving in lane 110, loop 104 needs constant supply of electrical energy, which is provided by wires that connect loop 104 to a roadside controller 108. When automobile 102 passes over loop 104, the electrical inductance of loop 104 changes. The change in inductance is used as a signal for detecting automobiles. Another loop 106 is installed on the next lane 112 of road 100.

What is needed is a low cost, low profile, energy self sufficient automobile detecting and reporting system to increase the number of monitoring points of traffic activity in a transportation network.

### BRIEF SUMMARY

The present invention provides a low cost, low profile, energy self sufficient automobile detecting and reporting system that would permit increasing the number of monitoring points of traffic activity in a transportation network.

In accordance with one aspect of the present invention, a device is provided for detecting an automobile. The device may be a detector that includes a body, an energy harvesting portion, a sensing portion, a processing portion and a communication portion. The energy harvesting portion can harvest energy from a source external to the body. The sensing portion can detect a parameter of the automobile and can output a signal based on the detected parameter. The processing portion can output a signature based on the signal. The communication portion can wirelessly transmit an output signal based on the signature. The energy harvesting portion can supply energy to each of the sensing portion, the processing portion and the communication portion.

In an example embodiment, the sensing portion is disposed on the body and is operable to detect electromagnetic radiation. For example, the device may be placed on the surface of the road to detect light from headlights of an approaching vehicle.

In an example embodiment, the sensing portion can detect one of a magnetic field, sound and electromagnetic radiation. In some embodiments, the sensing portion may detect a combination of a magnetic field, sound and electromagnetic radiation. In some example embodiments, the sensing portion is operable to detect infrared radiation, as the electromagnetic radiation. For example, each automobile may radiate a specific amount, e.g., magnitude, frequency, of infrared radiation, that may be detected.

In an example embodiment, the sensing portion can detect a parameter of the one of a magnetic field, sound and electromagnetic radiation, wherein the parameter includes one of magnitude and frequency.

In an example embodiment, the energy harvesting portion can harvest energy from one of vibrations, heat and electromagnetic radiation. In some embodiments, the energy harvesting portion can harvest energy from a combination of vibrations, heat and electromagnetic radiation.

In an example embodiment, the processing portion can output the signature as one feature of the signal.

In accordance with one aspect of the present invention, a system is provided that includes a first detector, a second detector and a data collector unit. The first detector included a first body, a first energy harvesting portion, a first sensing portion, a first processing portion, and a first communication portion. The first energy harvesting portion can harvest energy from a first source external to the first body. The first sensing portion can detect a first parameter and can output a first signal based on the first parameter. The first processing portion can output a first signature based on the first signal. The first communication portion can wirelessly transmit a first output signal based on the first signature. The first energy harvesting portion can further supply energy to each of the first sensing portion, the first processing portion and the first communication portion. The second detector included a second body, a second energy harvesting portion, a second sensing portion, a second processing portion, and a second communication portion. The second energy harvesting portion can harvest energy from a second source external to the second body. The second sensing portion can detect a second parameter and can output a second signal based on the second parameter. The second processing portion can output a second signature based on the second signal. The second communication portion can wirelessly receive the first output signal and can wirelessly transmit a second output signal based on the first output signal and the second signature. The second energy harvesting portion can further supply energy to each of the second sensing portion, the second processing portion and the second communication portion. The data collector unit includes a third communication portion and a third processing portion. The third communication portion can wirelessly receive the second output signal. The third processing portion can output a processed signal based on the second output signal.

In an example embodiment, the third communication portion can further wirelessly receive the first output signal.

In an example embodiment, the second communication portion can further wirelessly transmit the second output signal based solely on the second signature.

In an example embodiment, the third processing portion can further output the processed signal based on the first output signal and the second output signal.

In an example embodiment, the third processing portion is further operable to calculate a travel time based on the first output signal, the second output signal and a known distance between the first detector and the second detector.

Additional advantages and novel features of the invention are set forth in part in the description which follows, and in part will become apparent to those skilled in the art upon examination of the following or may be learned by practice of the invention. The advantages of the invention may be realized and attained by means of the instrumentalities and combinations particularly pointed out in the appended claims.

### BRIEF SUMMARY OF THE DRAWINGS

The accompanying drawings, which are incorporated in and form a part of the specification, illustrate an exemplary embodiment of the present invention and, together with the description, serve to explain the principles of the invention. In the drawings:

FIG. 1 is a planar view of key components in a conventional traffic measurement system;

FIG. 2 illustrates components of an example automobile detection device in accordance with aspects of the present invention;

FIG. 3A illustrates an example method for automobile detection and signature measurement at a time t₀ in accordance with aspects of the present invention;

FIG. 3B illustrates an example method for automobile detection and signature measurement at a time t₁ in accordance with aspects of the present invention;

FIG. 3C illustrates an example method for automobile detection and signature measurement at a time t₂ in accordance with aspects of the present invention;

FIG. 4 illustrates an example method of automobile detection and signature measurement in accordance with aspects of the present invention;

FIG. 5 is a planar view of an example traffic measurement system in accordance with aspects of the present invention; and

FIG. 6 illustrates an example automobile signature in accordance with aspects of the present invention.

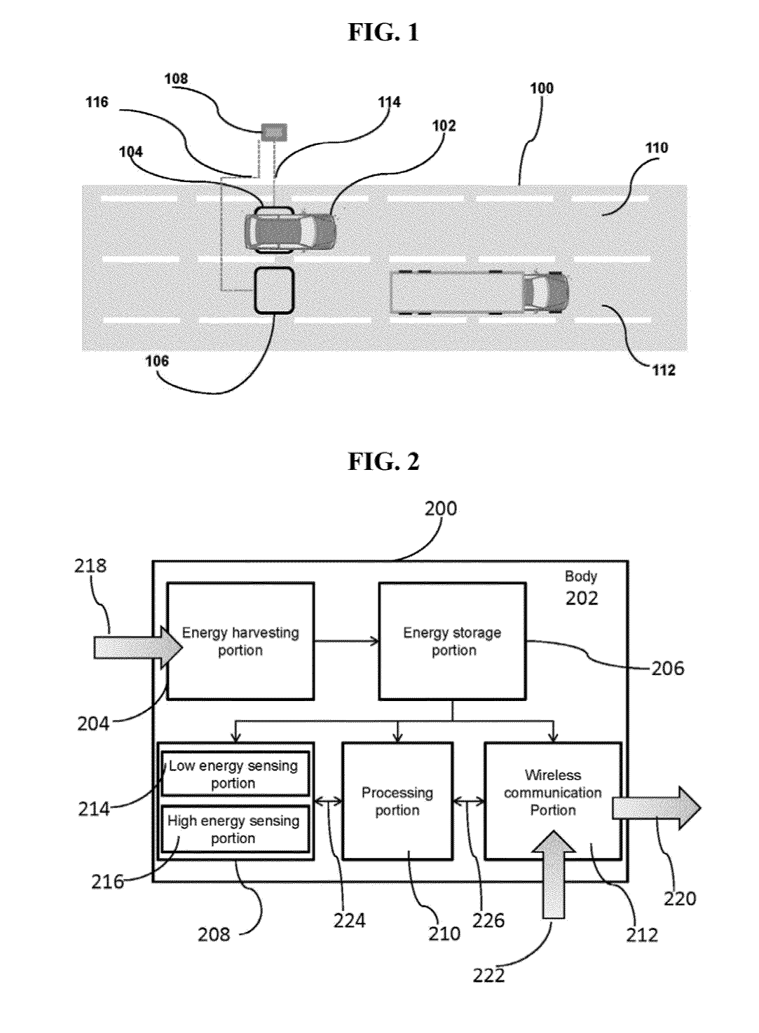

### DETAILED DESCRIPTION

An aspect of the present invention is drawn to a device and system for distributed traffic measurement in a transportation network. The device in present invention is a wireless energy efficient detector for detecting an automobile. The device is energy efficient by using two levels of energy for sensing parameters related to an automobile: a low-energy sensing portion and a high-energy sensing portion.

A device in accordance with an aspect of the present invention may perform low-energy sensing most of the time. Low-energy sensing may falsely detect an automobile. Therefore, every time the low-energy sensing portion detects an automobile, the detection may then be confirmed by a more accurate high-energy sensing portion. An example of low-energy sensing is detecting an automobile through the light intensity of its headlights. An example of high-energy sensing is detecting an automobile through its magnetic field.

A device in accordance with an aspect of the present invention is capable of calculating a signature for an automobile based on sensed parameters of the automobile. In particular, a detector may sense, a parameter, e.g., magnetic field of an automobile, and generate a signal based on the sensed parameter. This signal may be transformed into a signature based on a feature of the signal. For example, the magnitude and spacing of maximum values of the signal may be a feature that is used to generate a signature. Accordingly, the signature will have much less data than the signal, but will have sufficient data to distinguish the associated automobile from other automobiles. Such signatures help to re-identify the same automobile when it is detected by another detector. Therefore, if two detectors are used in a road at known distances, the average speed of the automobile can be calculated between the pair of detectors. As an example and in a preferred mode of operation, the detectors are small size devices that are similar to lane markers (also known as road studs).

A system in accordance with an aspect of the present invention may include a combination of at least two detectors and a data collector unit, e.g., a roadside device, that can communicate wirelessly to at least one of the detectors. The automobile signatures collected by each detector can be wirelessly transmitted to the roadside device. The roadside device can, use the signatures for processing, non-limiting examples of which include traffic count calculation, and average speed estimation.

In one example embodiment, if a detector is within the communication range of the roadside device, transmission of signatures collected by the detector to the roadside device may occur through direct wireless communication. In other example embodiments, a detector communicates to the roadside device through a multi-hop path, wherein signatures are transmitted through other detectors that are within direct wireless communication range from one another.

Since a device in accordance with an aspect of the present invention is energy efficient, it can become completely energy self sufficient by harvesting its energy from surrounding energy sources, non-limiting examples of which include ambient light, vibration, acoustic energy and heat gradient.

FIG. 2 illustrates an example of an automobile detector 200 in accordance within aspects of the present invention.

As illustrated in the figure, automobile detector 200 includes a body 202, an energy harvesting portion 204, an energy storage portion 206, a sensing portion 208, a processing portion 210, and a wireless communication portion 212. Sensing portion 208 includes a low-energy sensing portion 214 and a high-energy sensing portion 216.

Energy harvesting portion 204 is arranged to receive energy from external sources to automobile detector 200.

Energy harvesting portion 204 is operable to convert the received energy into electrical energy. Energy harvesting portion 204 may convert any kind of energy in surrounding environment of automobile detector 200 into electrical energy. Any known energy harvesting device may be used in energy harvesting portion 204, non-limiting examples of which include energy harvesting devices that harvest light energy, vibration, heat gradient, electromagnetic radiation, near field magnetic energy, and acoustic energy.

Energy storage portion 206 is arranged to store the electrical energy provided by energy harvesting portion 204 and supply the energy to sensing portion 208, processing portion 210 and wireless communication portion 212.

Any known energy storage device may be used in energy storage portion 206, Non-limiting examples of which include a battery, a capacitor, a super-capacitor, or an ultra-capacitor.

Sensing portion 208 is operable to sense a number of predefined parameters, non-limiting examples of which include light, magnetic field intensity, electromagnetic radiation, infrared radiation, temperature, and acoustic noise. In some embodiments, sensing portion 208 may sense one parameter, whereas in other embodiments, sensing portion 208 may sense several parameters.

In a specific embodiment, sensing portion 208 includes low-energy sensing portion 214 and high-energy sensing portion 216. The amount of electrical power consumption for operation of low-energy sensing portion 214 is smaller than the level of electrical power consumption for operation of high-energy sensing portion 216.

Non-limiting example of parameters that may be sensed by low-energy sensing portion 214 include acoustic noise, vibration, and light intensity.

Because low-energy sensing portion 214 constantly senses a set of parameters to detect an automobile, it is important that it consumes a very small amount of energy. However, the low-energy consumption affects the detection performance of low-energy sensing portion 214, and thus it may falsely detect an automobile with a certain probability. For example an automobile in adjacent lane of the detector may be falsely detected by the low-energy sensing portion, because the headlight of the automobile may expand over multiple lanes. Therefore, when low-energy sensing portion 214 detects an automobile, its detection must be confirmed by high-energy-sensing portion, 216, which has a much smaller probability of falsely detecting an automobile.

Non-limiting examples of parameters that may be detected by high-energy sensing portion 216 include weight, light intensity, magnetic field intensity, electromagnetic radiation, temperature, infrared radiation, vibration, and acoustic energy.

Detecting parameters through high-energy sensing, the accuracy and reliability of measuring the parameters related to an automobile are much higher compared to accuracy and reliability of low-energy sensing. By measuring parameters such as magnetic field, it can be confirmed that the automobile travels within the lane that the detector is monitoring and thus the probability of false detections is significantly reduced.

Processing portion 210 is operable to receive data from sensing portion 208 and data from wireless communication portion 212.

Wireless communication portion 214 is operable to transmit and receive data. Wireless communication portion 214, is operable to transmit a transmit signal 220 and receive a receive signal 222.

In operation, energy harvesting portion 204 receives energy 218 from energy sources external to automobile detector 200, and converts received energy 218 into electrical energy. The electrical energy is stored in energy storage portion 206, which provides electrical energy to sensing portion 208, processing portion 210, and wireless communication portion 212.

If low-energy sensing portion 214 detects an automobile, it sends a signal to processing portion 210, through an interface 224. Then, processing portion 210 uses interface 224 to activate high-energy sensing portion 216 to confirm presence of the automobile.

In another embodiment, if low-energy sensing portion 214 detects an automobile, it may activate high-energy sensing portion 216. At this point, high-energy sensing portion 216 may confirm presence of the automobile.

After an automobile is detected and its presence is confirmed by sensing portion 208, a set of predefined parameters of the automobile are processed and analyzed by processing portion 210. In an example embodiment, processing portion 210 converts the data provided by sensing portion 208 into a signature of the automobile. A more detailed discussion regarding calculating an automobile's signature will be provided later.

In an example embodiment, it may be needed to communicate the signature of an automobile to other devices, in which case, processing portion may use interface 226 to send the signature of the automobile to wireless communication portion 212 for transmission.

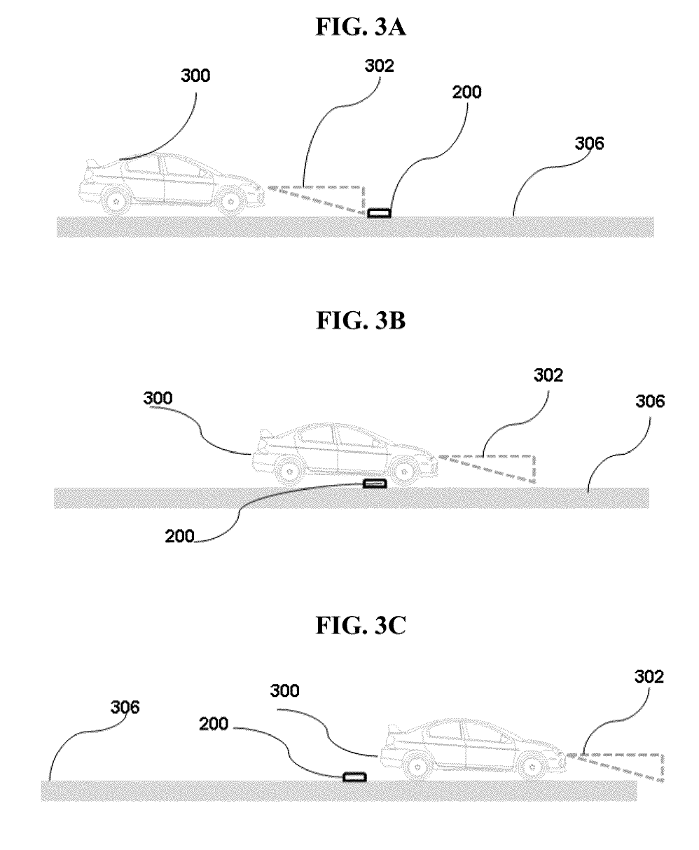

An example method, in accordance with aspects of the present invention, of using detector 200 will now be described with reference to FIGS. 3A-3C.

FIG. 3A illustrates an example method for automobile detection and signature measurement at a time t₀ in accordance with aspects of the present invention. This figure shows a side view of a road 306 with automobile detector 200.

In FIG. 3A, an automobile 300 projects light beams 302. For purposes of discussion, detector 200 is operable to detect light. Detector 200 is therefore able to detect automobile 300 via light beams 302 as automobile 300 approaches detector 200.

Returning to FIG. 2, before an automobile approaches detector 200, high-energy sensing portion 216 and processing portion 210 are in inactive mode (also known as sleep mode) in order to save power consumption of detector 200. Low-energy sensing portion 214 is the only portion that is actively sensing parameters. When automobile 300 approaches detector 200, low-energy sensing portion 214 detects its light beams 302. At this point, low-energy sensing portion 214 sends a signal to processing portion 210 through interface 224 indicating presence of an approaching automobile. Then processing portion 210 activates high-energy sensing portion 216 to confirm presence of automobile 300.

FIG. 3B illustrates an example method for automobile detection and signature measurement at a time t₁ in accordance with aspects of the present invention

FIG. 3B illustrates a situation where the presence of automobile 300 is confirmed by high-energy sensing portion 216. At time t₁, low-energy sensing portion 214 will have detected automobile 300 and processing portion 210 and high-energy sensing portion 216 will have been activated. High-energy sensing portion 216 consumes electrical energy at a higher rate than low-energy sensing portion 214. However, it has a higher detection accuracy and reliability. In this example, high-energy sensing portion 216 may sense magnetic field or infrared radiation to confirm presence of automobile 300.

Returning FIG. 3B, as long as automobile 300 is present over detector 200, high-energy sensing portion 216 performs sensing of a set of predefined parameters and provides data to processing portion 210. Then processing portion 210 converts this data into a signature, which will be explained in more details later.

FIG. 3C illustrates an example method for automobile detection and signature measurement at a time t₂ in accordance with aspects of the present invention.

As shown in this figure, at time t₂, automobile 300 has passed over detector 200.

Returning to FIG. 2 high-energy sensing portion 216 no longer detects the parameter(s) associated with automobile 300. Accordingly, high-energy sensing portion 216 sends a deactivation trigger signal to processing portion 210. High-energy sensing portion then stops sensing to reduce energy consumption.

In the above-discussed example embodiments discussed with reference to FIGS. 3B and 3C, high-energy sensing portion only operates while it senses the predefined parameter(s) associated with automobile 300. In other embodiments, high-energy sensing portion 216 is operable to sense the predefined parameter(s) associated with automobile 300 for a predefined period of time. For example, when low-energy sensing portion 214 detects an automobile, high-energy sensing portion 216 may be operational for a period of microseconds. Of course, a period of microseconds is merely provided as an example of an operational time period, wherein high-energy sensing portion 216 may be operational for any predefined time period.

In an example embodiment, low-energy sensing portion 214 may constantly perform sensing, because it consumes a very low level of energy. In other embodiments, low-energy sensing portion 214 may start and stop sensing on command or according to a predefined schedule to further reduce its energy consumption.

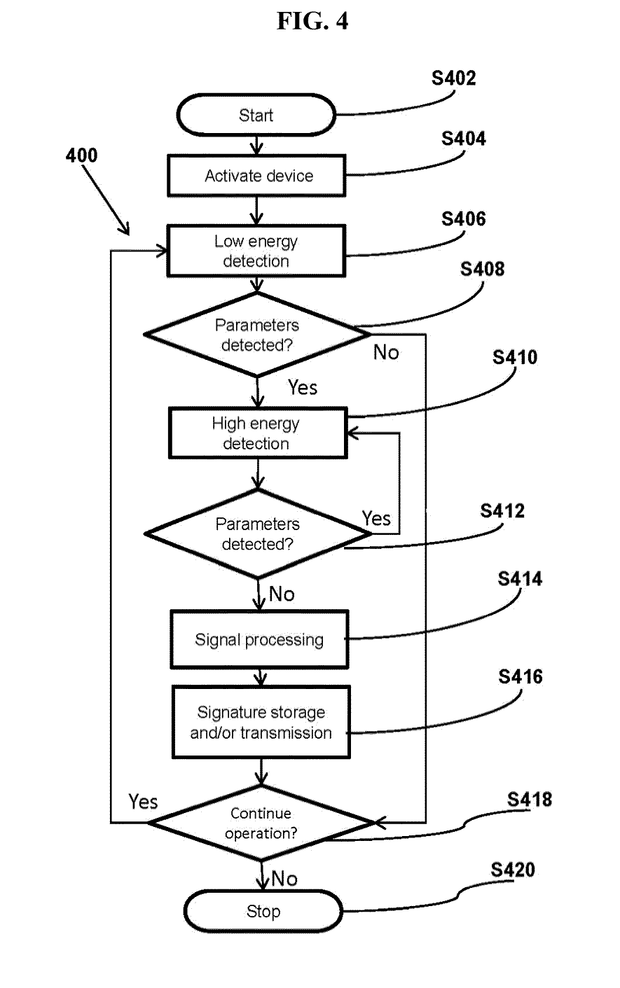

An example method of using a system in accordance with an aspect of the present invention will now be described with additional reference to FIGS. 4-6.

FIG. 4 illustrates an example method 400 of automobile detection and signature measurement in accordance with aspects of the present invention.

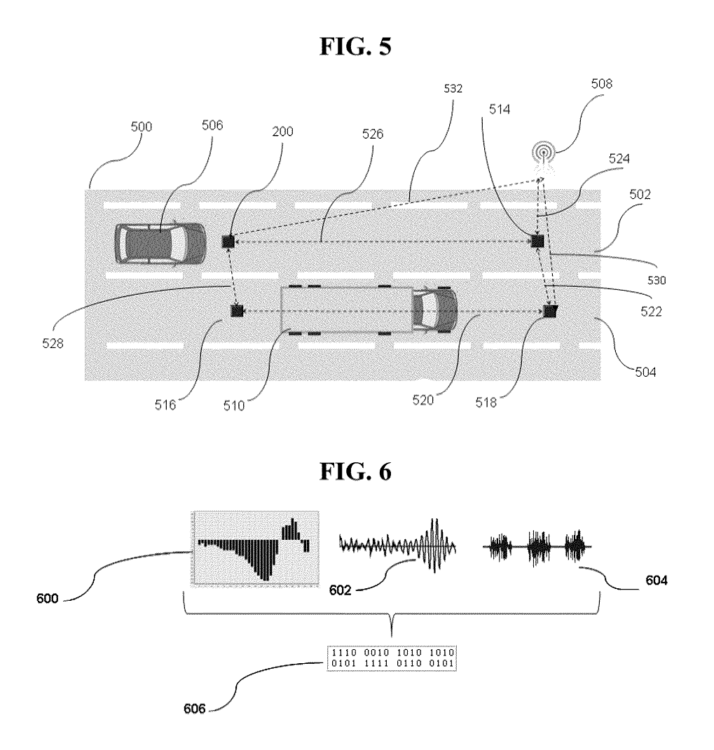

FIG. 5 is a planar view of an example traffic measurement system in accordance with aspects of the present invention.

In the figure, a road 500 has two lanes 502 and 504. Four detectors 200, 514, 516 and 518, in accordance with aspects of the present invention, are positioned at road 500. An automobile can be detected by any of detectors 200, 514, 516 and 518, over which the automobile moves. As an example, automobile 506 is detected when it moves over detector 200 or detector 514. Likewise, truck 510 is detected when it moves over detector 516 or detector 518. A data collector unit 508 is positioned near road 500. Data collector unit 508 includes communication portion (not shown) and a processing portion (not shown). The communication portion can wirelessly receive signals from any of detectors 200, 514, 516 and 518, as will be discussed in greater detail below. The third processing portion can output a processed signal based on the received signals, as will be discussed in greater detail below.

Detector 200 and detector 514 are positioned in lane 502 at predetermined distance from each other. Similarly, detector 516 and detector 518 are positioned in lane 504 at predetermined distance from each other.

Detector 200 and detector 514 may communicate with each other using a wireless communication link 526. Detector 200 may communicate with data collector unit 508 using a wireless communication link 532. Detector 514 may communicate with data collector unit 508 using a wireless communication link 524.

Detector 516 and detector 518 may communicate with each other using a wireless communication link 520. Detector 516 may communicate with data collector unit 508 using a wireless communication link 534. Detector 518 may communicate with data collector unit 508 using a wireless communication link 530.

Detector 200 and detector 516 may communicate with each other using a wireless communication link 528. Detector 518 and detector 514 may communicate with each other using a wireless communication link 522.

Returning to FIG. 4 and FIG. 2, method 400 starts (S402) and detector 200 constantly harvests energy using energy harvesting portion 204. As soon as energy that is stored in energy storage portion 206 reaches the minimum level for operation of circuits, detector 200 is activated (S404) by providing electrical energy to sensing portion 208, processing portion 210, and communication portion 212.

Once detector 200 is activated, even though all portions of detector 200 may be connected to electrical power, only low-energy sensing portion 214 is active by constantly performing sensing (S406). Returning to FIG. 2, low-energy sensing portion 214 senses predefined parameters.

It is then determined whether the predefined parameter(s) is detected (S408). Returning to FIG. 2 and FIGS. 3A-3C, for purpose of discussions, low-energy portion 214 is arranged to sense light. If the predefined parameter is not detected, it is then determined whether or not to continue operation of the detector (S418).

However, in the instance that low-energy sensing portion 214, detects the predefined parameters (S408), then detector 200 performs high-energy sensing (S410). For example, as illustrated in FIG. 3A, presume that automobile 300 is approaching detector 200 such that light beams 302 hit detector 200. At this point low-energy sensing portion 214 senses light, and based on that, detects approaching automobile 300. As discussed above with reference to FIG. 2, and FIG. 3B, high-energy sensing portion 216 senses one or a number of parameters to confirm presence of automobile 300.

It is then determined whether predefined parameter(s) are detected (S412). Returning to FIG. 2 and FIG. 3B, high-energy sensing portion 216 constantly performs sensing and providing data to processing portion 210. High-energy sensing operation continues as long as high-energy sensing portion 216 detects the predefined parameter(s) as an indication of presence of automobile 300 over detector 200.

If predefined parameter(s) are detected, then high-energy sensing portion 216 continues to sense for the parameters(s) (S410).

However, if predefined parameter(s) are no longer detected, then a signal is processed (S414). Returning to FIG. 2 and FIG. 3C, when automobile 300 passes detector 200, high-energy sensing portion 216 will no longer detect the predefined parameters that indicate a presence of an automobile. Detector 200 will then start signal processing of data provided by the sensing portion (S414) and high-energy sensing 216 is deactivated. In some embodiments, deactivation of high-energy sensing portion 216 occurs through a deactivation trigger signal provided by processing portion 210. In some embodiments, deactivation of high-energy sensing portion 216 occurs through a deactivation trigger signal provided by high-energy sensing portion 216 itself. The purpose of the signal processing is to convert data of sensing portion 208 into a signature of a detected automobile. This will be explained in further detail with reference to FIG. 6.

An example of signature generation will now be described in FIG. 6.

FIG. 6 illustrates an example automobile signature in accordance with aspects of the present invention.

In the figure, a number of parameters are sensed by sensing portion 208, and the data is provided to processing portion 210. In this example, the data includes a function for an automobile's sensed magnetic field intensity over time 600, a function of automobile's sensed vibration over time 602, and a function of automobile's sensed acoustic energy over time 604. Based on this data, detector 200 calculates a signature 606 of the corresponding automobile (S414).

For communication efficiency, the information in signature 608 contains reduced information of data provided by the sensing portions of detector 200. In other words, signature 608 may be based on a feature or plurality of features of the data provide by the sensing portions of detector 200. This data reduction is important both for communication and energy efficiency. For example, transmitting the complete data generated by sensing portion 208 requires transmitting time and power for a waveform 600 corresponding to an automobile's magnetic field intensity over time, a waveform 602 corresponding to vibrations resulting from the automobile over time, and a waveform 604 corresponding to an acoustic energy of the automobile over time. Transmitting these waveforms 600, 602 and 604 in their entirety, would require a large amount of data, which requires a lot of energy. Accordingly, generating a signature, based on a feature(s) of waveforms 600, 602 and 604, will reduce transmitting time and power. Non-limiting examples of information in signature 606 include: maximum value for a parameter, minimum value for a parameter, the number of local maximums and local minimums in the parameters, average of a parameter, standard deviation of a parameter and distribution characteristics of parameters.

An important advantage of generating a signature is that it reduces the amount of data required to be transmitted, while maintaining sufficient data to distinguish between different automobiles. In other words by applying data reduction and signature calculation, only the parts of collected data that are essential for re-identification of an automobile are stored and transmitted which reduces the energy consumption by detector 200.

Returning to FIG. 4, after a signature of an automobile is generated, it may be stored in memory of detector 200, or it may be wirelessly communicated to other devices (S416). Referring back to FIG. 2, in some embodiments, processing portion 210 may send the signature to wireless portion 212 for transmission. In other embodiments, processing portion 210 may store the signature in a memory (not shown) of processing portion 210.

It is then determined whether the detecting operation should continue (S418). In some embodiments, detector 200 may automatically deactivate after a predetermined period of time. In other embodiments, detector 200 may deactivate based on an instruction wirelessly received from an external device.

If it is determined that the detecting operation should continue, then detector 200 again performs low-energy detection (S406).

If it is determined that the detecting operation should not continue, then method 400 stops (S420).

The example embodiments discussed above deal with initially detecting parameters associated a presence of an automobile using a single detector. In accordance with other aspects of the present invention, a system with two or more detectors may be used to determine more aspects of an automobile such as its travel time and average speed. This may be accomplished using a second detector and a data collector unit as described below.

When the automobile 506 is moving in lane 502, it first passes over detector 200, where its signature is calculated.

Detector 200 may directly transmit the signature of automobile 506 to data collector unit 508 using wireless communication link 532. In other embodiments, detector 200 may transmit the signature to detector 514 using wireless communication link 526, wherein detector 514 may then transmit the signature to roadside data collector device 508 using wireless communication link 524.

Now that automobile 506 has passed over detector 200, when automobile 506 passes over detector 514, a signature associated with automobile 506 is calculated by device 514 and is communicated to roadside data collector device 508 using wireless communication link 524.

For automobile 506, data collector unit 508 receives two signatures, one calculated by detector 200 and one calculated by detector 514. Since the two signatures of automobile 506 are similar, data collector unit 508 is able to match them in order to re-identify the automobile 506 at the location of detector 514. Automobile 506 has been previously identified at the location of detector 200.

Data collector unit 508 may calculate the travel time of automobile 506 between detector 200 and detector 514. Specifically, data collector unit 508 may calculate the difference between the time that it received the signature of automobile 506 calculated by detector 200 and the time that it received signature of automobile 506 calculated by detector 524.

By dividing the calculated travel time over the distance between detectors 200 and 514, data collector unit 508 is able to calculate the average speed of automobile 506.

In a similar manner, the speed of another automobile 510 in lane 504 may be calculated by data collector device 508 based on the signatures generated by detectors 516 and 518 on a lane 522.

In a high automobile traffic situation, many automobiles may be detected by detectors 506 and detector 200 in lane 502. However because different parameters of each automobile is detected and used for signature calculation by each detector 200 and 506, roadside collector unit 508 will be able to re-identify individual automobiles by matching their signatures among a collection of signatures reported by both detectors over time.

In the example method of using a system in accordance with an aspect of the present invention discussed above, low-energy sensing portion 214 constantly senses a set of parameters to detect an automobile. However, in other embodiments, low-energy sensing portion 214 may have predefined sleep modes to save power.

The example embodiment detectors discussed above may be used to detect automobiles. In other embodiments, detectors may be used to detect other types of vehicles, non-limiting examples of which include bicycles and motorcycles.

The example embodiment detectors discussed above may be used to detect automobiles that move on roadways. In other embodiments, detectors may be used to detect trains travelling on railroads. For example, a detector may detect some aspects of a train such as its presence, speed and length. In still other embodiments, detectors may be used to detect a combination of automobiles and trains, to avoid crashes in railway-roadway grade crossings. For example, the presence and speed of automobiles and trains on the intersecting roadway and railway may be reported by detectors to a data collector. The detection may trigger safety related alarms and devices to minimize the probability of collision between trains and automobiles.

In addition to roadways, a detector in accordance with aspects of the present invention may be used on other transportation facilities, non-limiting examples of which include automobile parking facilities. By placing one detector on each automobile parking spot of a parking facility, the presence of an automobile (or motorcycle) at each parking spot may be detected as an indication of availability of that parking spot. The data can be transmitted wirelessly either directly to a data collector unit or to the neighboring detectors. A real-time parking management application may use the data provided by all detectors on the parking facility to report the parking availability and enforce parking management rules. Similarly, detectors monitoring aircraft and vehicular traffic on airport runways and taxiways could greatly improve airport safety, virtually eliminating runway incursions and collisions.

A system in accordance with aspects of the present invention may be used for ramp metering. In an example arrangement, one or more detectors may be used to monitor all automobiles entering the ramp (on-ramp) and all automobiles that exit the ramp (off-ramp). Therefore, a system of the detectors can monitor the average number of automobiles in the ramp, also known as the ramp queue length. Knowing the ramp queue length may help improve the timing of the ramp. In a similar arrangement of detectors, the average queue length of automobiles in intersections with traffic lights may be measured. This information can help optimize the timing of the traffic light.

In accordance with another aspect of the present invention, a detector may additionally be used as a lane marker (also know as road studs). Additionally, a roadside data collector in accordance with aspects of this invention may be co-located with the mileage markers, located every 1/10^{th} mile on a highway. The advantage of this integration is incorporating geopositioning information into the data collection system. Precisely known locations and standard separation helps to detect unexpected changes in traffic flow rates using simple algorithms.

A system in accordance with aspects of the present invention may be used in areas where conventional energy and communication infrastructure does not exist, a non-limiting example of which includes remote rural areas and borders. As such, a system in accordance with aspects of the present invention would enable traffic monitoring and surveillance.

In a system in accordance with aspects of the present invention, the roadside data collector unit may be connected to communication infrastructure to communicate its real time data to a remote entity in a timely fashion. Non-limiting examples of communication modes between the roadside data collector and the remote office are cellular infrastructure, satellite communication links, and landline communication cable. Through, this communication, the information collected by roadside data collector device may be transmitted to control or operation entities, non-limiting examples of which include police department, patrol officers, real time travel advisory systems, fire department, and ambulance dispatching centers. Non-limiting examples of information that that data collector device transmit to these entities are per lane automobile count, average travel speed, and average lane occupancy.

A system in accordance with aspects of the present invention may be used for automatic gate control. For example, a gate controller may be arranged to open or close a gate upon detection of an automobile at the gate using the detectors.

The foregoing description of various preferred embodiments of the invention have been presented for purposes of illustration and description. It is not intended to be exhaustive or to limit the invention to the precise forms disclosed, and obviously many modifications and variations are possible in light of the above teaching. The example embodiments, as described above, were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed as new and desired to be protected by Letters Patent of the United States is:

1. A device, for detecting an automobile, said device comprising:
a body;
an energy harvesting portion operable to harvest energy from a source external to said body;
a sensing portion operable to detect a parameter of the automobile and to output a signal based on the detected parameter;
a processing portion operable to output a signature based on the signal; and
a communication portion operable to wirelessly transmit an output signal based on the signature,
wherein said energy harvesting portion is operable to supply energy to each of said sensing portion, said processing portion and said communication portion.

2. The device of claim 1, wherein said sensing portion is disposed on said body and is operable to detect electromagnetic radiation.

3. The device of claim 1, wherein said sensing portion is operable to detect one of a magnetic field, sound and electromagnetic radiation.

4. The device of claim 3, wherein said sensing portion is operable to detect infrared radiation.

5. The device of claim 3,
wherein said sensing portion is operable to detect a parameter of the one of a magnetic field, sound and electromagnetic radiation, and
wherein the parameter includes one of magnitude and frequency.

6. The device of claim 1, wherein said energy harvesting portion is operable to harvest energy from one of vibrations, heat and electromagnetic radiation.

7. The device of claim 1, wherein said processing portion is operable to output the signature as one feature of the signal.

8. A system comprising:
a first detector including a first body, a first energy harvesting portion, a first sensing portion, a first processing portion, and a first communication portion, said first energy harvesting portion being operable to harvest energy from a first source external to said first body, said first sensing portion being operable to detect a first parameter and to output a first signal based on the first parameter, said first processing portion being operable to output a first signature based on the first signal, said first communication portion being operable to wirelessly transmit a first output signal based on the first signature, said first energy harvesting portion being further operable to supply energy to each of said first sensing portion, said first processing portion and said first communication portion;
a second detector including a second body, a second energy harvesting portion, a second sensing portion, a second processing portion, and a second communication portion, said second energy harvesting portion being operable to harvest energy from a second source external to said second body, said second sensing portion being operable to detect a second parameter and to output a second signal based on the second parameter, said second processing portion being operable to output a second signature based on the second signal, said second communication portion being operable to wirelessly receive the first output signal and to wirelessly transmit a second output signal based on the first output signal and the second signature, said second energy harvesting portion being further operable to supply energy to each of said second sensing portion, said second processing portion and said second communication portion; and
a data collector unit including a third communication portion and a third processing portion, said third communication portion being operable to wirelessly receive the second output signal, said third processing portion being operable to output a processed signal based on the second output signal.

9. The system of claim 8, wherein said third communication portion is further operable to wirelessly receive the first output signal.

10. The system of claim 9, wherein said second communication portion is further operable to wirelessly transmit the second output signal based solely on the second signature.

11. The system of claim 10, wherein said third processing portion is further operable to output the processed signal based on the first output signal and the second output signal.

12. The system of claim 11, wherein said third processing portion is further operable to calculate a travel time based on the first output signal, the second output signal and a known distance between said first detector and said second detector.

13. A method of detecting an automobile, said method comprising:
harvesting first energy, via a first energy harvesting portion, from a first energy source;
converting the first harvested energy from the first energy source into first electrical energy;
providing the first electrical energy to a first sensing portion, a first processing portion, and a first communication portion;
harvesting second energy, via a second energy harvesting portion, from a second energy source;
converting the second harvested energy from the second energy source into second electrical energy;
providing the second electrical energy to a second sensing portion, a second processing portion, and a second communication portion;
detecting, via the first sensing portion, a first parameter;
outputting a first signal based on the first parameter;
outputting, via the first processing portion, a first signature based on the first signal;
wirelessly transmitting, via the first communication portion, a first output signal based on the first signature;
detecting, via the second sensing portion, a second parameter;
outputting a second signal based on the second parameter;
outputting, via the second processing portion, a second signature based on the second signal;
wirelessly receiving, via the second communication portion, the first output signal;
wirelessly transmitting, via the second communication portion, a second output signal based on the first output signal and the second signature;
wirelessly receiving, via a third communication portion, the second output signal; and
outputting, via a third processing portion, a processed signal based on the second output signal.

14. The system of claim 13, further comprising wirelessly receiving, via the third communication portion, the first output signal.

15. The system of claim 14, wherein said outputting, via a third processing portion, a processed signal based on the second output signal comprises outputting the processed signal based on the first output signal and the second output signal.

16. The system of claim 15, further comprising calculating, via the third processing portion, a travel time based on the first output signal, the second output signal and a known distance between the first sensing portion and the second sensing portion.

17. The system of claim 16, wherein said detecting, via the first sensing portion, a first parameter comprises:
detecting, via a first low-energy sensing portion, a third parameter using a first amount of energy; and
detecting, via a first high-energy sensing portion, a fourth parameter using a second amount of energy,
wherein the first amount of energy is less than the second amount of energy.

18. The system of claim 17, wherein said detecting, via the second sensing portion, a second parameter comprises:
detecting, via a second low-energy sensing portion, the third parameter using the first amount of energy; and
detecting, via a second high-energy sensing portion, the fourth parameter using the second amount of energy.
